(19) United States
(12) Patent Application Publication
(10) Pub. No.: US 2015/0049782 A1
(43) Pub. Date: Feb. 19, 2015

(54) Thermal Substitution Power Measurement System with RF Self-Heating Temperature Sensor

(71) Applicant: Keysight Technologies, Inc., Minneapolis, MN (US)

(72) Inventor: Richard K. Karlquist, Galt, CA (US)

(21) Appl. No.: 13/966,862

(22) Filed: Aug. 14, 2013

(51) Int. Cl. G01K 17/00; G01R 21/02

(52) U.S. Cl. CPC G01K 17/00; G01R 21/02
USPC 374/32

(57) ABSTRACT

A thermal substitution power measurement system includes an electromechanically-resonant temperature sensor, a temperature measurement circuit coupled to the temperature sensor, an RF power source, and a power controller. The temperature sensor has a temperature-dependent resonance at a first frequency. The temperature measurement circuit generates a temperature signal dependent on the first frequency. The RF power source delivers to the temperature sensor a controllable level of RF power at a second frequency corresponding to a resonance of the temperature sensor and outputs a measure of the RF power delivered to the temperature sensor. The power controller operates in response to the temperature signal to control the RF power delivered to the temperature sensor to maintain the temperature signal constant notwithstanding variations in external power input to the temperature sensor.

### BACKGROUND

Calorimeters are used in such applications as measuring RF, microwave, or optical power, and measuring the heat generated by a chemical reaction for the purpose of determining the characteristics of the reaction or the constituent reagents. Heat is the time integral of power. Modern calorimeters employ an electronic thermometer to measure temperature.

A basic conventional electronic calorimeter applies the power or heat to be measured to an electronic thermometer and measures the temperature rise of the electronic thermometer. To convert the temperature rise to heat in joules or power in watts, it is necessary calibrate the calorimeter by determining the heat capacity of the thermometer, in units of joules per degree. This can be determined by applying a known amount of heat to the thermometer using a calibration heater and observing the temperature rise. One source of error to which the calibration process is subject is that not all of the heat generated by the calibration heater is transferred to the electronic thermometer. Therefore, it is desirable for the electronic thermometer to have a self-heating capability. In an example, a thermistor is used as the electronic thermometer. The thermistor has a resistance that is a known function of temperature, and can also be self heated by passing a DC or low-frequency AC electric current through it. The heat generated in the thermistor can be accurately measured by measuring the voltage across the thermistor and the current through it.

Some conventional electronic calorimeters implement continuous self calibration by using a feedback system to stabilize the temperature of the thermistor. In the quiescent state, a known amount of DC or low-frequency AC power (internal power) is applied to the thermistor to maintain the temperature of the thermistor at a set temperature higher than ambient temperature. When the external power (e.g., microwave power) or heat (e.g., heat generated by a chemical reaction) is applied to the thermistor, the thermal stabilization system automatically reduces the internal power by an amount exactly equal to the external power applied to the thermistor to maintain the thermistor at its set temperature. The reduction in the internal power thus provides a measure of the external power applied to the thermistor. Additionally or alternatively, the reduction in the internal power integrated over time provides a measure of the external heat applied to the thermistor. Using low-frequency AC internal heating instead of DC internal heating reduces flicker (1/f) noise and thermoelectric effects that occur with DC internal heating. Typically, AC internal heating at a frequency in the range from 1 to 10 kHz is used. This technique is employed in the Hewlett-Packard 431A Power Meter, described in 1961 in the HP Journal: http://www.hpl.hp.com/hpjournal/pdfs/IssuePDFs/1961-06.pdf.

Electronic thermometers based on quartz resonators offer a number of advantages, such as stability, small size, and high sensitivity in calorimetric applications. However, quartz resonator-based electronic thermometers have not been widely used to measure temperature in self-heating thermal substitution power or heat measurement systems because conventional self-heating techniques, such as those described above, are not effective to self-heat a quartz resonator. What is needed, therefore, is way to internally self-heat a quartz resonator-based electronic thermometer in a thermal substitution power or heat measurement system.

### BRIEF DESCRIPTION OF THE DRAWINGS

FIG. 1 is a block diagram showing an example of a thermal substitution power measurement system.

FIG. 2 is a schematic diagram showing an example of a temperature measurement circuit.

FIGS. 3 and 4 are block diagrams showing additional examples of a temperature measurement circuit.

FIGS. 5-7 are block diagrams showing examples of a variable RF power source.

FIGS. 8-10 block diagram showing examples of a power measurement circuit.

FIG. 11 is a block diagram showing an example of a simpler thermal substitution power measurement system.

FIGS. 12-14 are block diagrams showing other examples of a simpler thermal substitution power measurement system.

### DETAILED DESCRIPTION

Disclosed herein is a thermal substitution power measurement system that includes an electromechanically-resonant temperature sensor, a temperature measurement circuit coupled to the temperature sensor, a variable RF power source, and a power controller. The temperature sensor has a resonance at a first frequency that varies in response to changes in temperature of the temperature sensor. The temperature measurement circuit is to generate a temperature signal dependent on the first frequency. The variable RF power source is to deliver to the temperature sensor a controllable level of RF power at a second frequency corresponding to a resonance of the temperature sensor, and is additionally to output a measure of the RF power delivered by the variable RF power source to the temperature sensor; the power controller operates in response to the temperature signal to control the level of the RF power delivered by the variable RF power source to the temperature sensor to maintain the temperature signal constant notwithstanding variations in external power input to the temperature sensor.

Also disclosed herein is thermal substitution power measurement system that includes an electromechanically-resonant temperature sensor having a resonance at a first frequency dependent on temperature, a passive temperature measurement circuit, a variable RF power source, and a power controller. The temperature sensor has a resonance at a first frequency that varies in response to changes in temperature of the temperature sensor. The temperature measurement circuit is to generate a temperature signal dependent on the first frequency. The variable RF power source is to deliver to the temperature sensor a controllable level of RF power at a frequency corresponding to the first frequency and is additionally to output a measure of the RF power delivered by the variable RF power source to the temperature sensor. The power controller is to control the level of the RF power delivered by the variable RF power source to the temperature sensor to maintain the temperature signal constant notwithstanding variations in external power input to the temperature sensor.

In an embodiment, the power measurement system additionally includes a transformer, a bridge circuit, and frequency control circuit. The transformer has a secondary winding and a center-tap primary winding. The bridge circuit is electrically connected to the variable RF power source. The frequency control circuit operates to match the frequency of the variable RF power source to changes in the resonant frequency of the temperature sensor due to phase shifts caused by changes in the level of the RF power delivered by the variable RF power source. The temperature sensor and a resistor constitute two adjacent arms of the bridge, the center-tap primary winding of the transformer constitutes the remaining two arms of the bridge; and the secondary winding of the transformer outputs an error signal to the frequency control circuit.

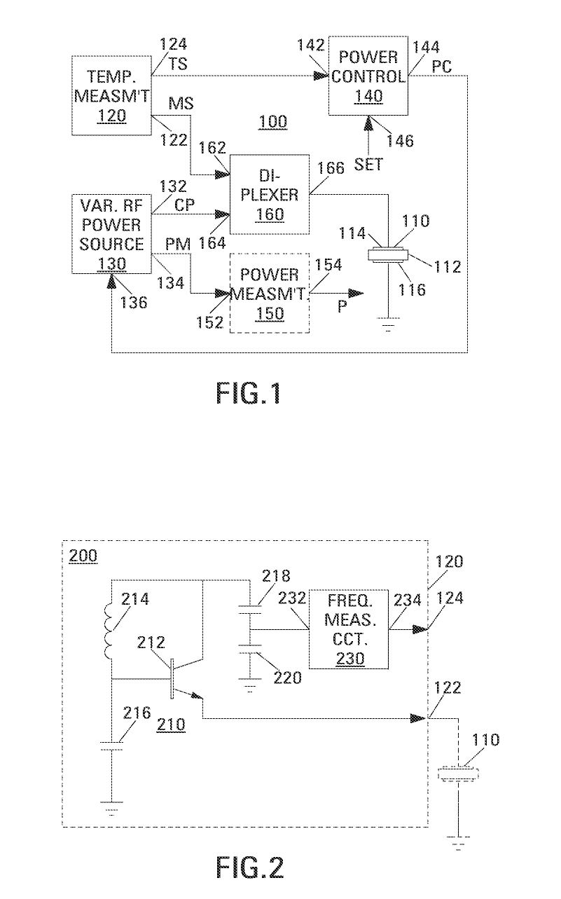

FIG. 1 is a block diagram showing an example 100 of a thermal substitution power measurement system. For brevity, a thermal substitution power measurement system will be referred to herein as a power measurement system. References in this Detailed Description to a power measurement system are to be taken to refer to a thermal substitution power measurement system. Power measurement system 100 includes an electromechanically-resonant temperature sensor 110, a temperature measurement circuit 120 coupled to temperature sensor 110, a variable RF power source 130, and a power controller 140. For brevity, an electromechanically-resonant temperature sensor will be referred to herein simply as a temperature sensor. References in this Detailed Description to a temperature sensor are to be taken to refer to an electromechanically-resonant temperature sensor. The example shown in FIG. 1 additionally includes an optional power measurement circuit 150 and a diplexer 160.

Diplexer 160 couples an RF measurement signal MS output by temperature measurement circuit 120 and a controlled level of RF power CP output by variable RF power source 130 to temperature sensor 110 in a way that prevents undesirable interactions between the temperature measurement circuit and the variable RF power source. Typically, depending on the relative frequencies of measurement signal MS and RF power CP, diplexer 160 is composed of two band-pass filters or a high-pass filter and a low-pass filter.

Temperature sensor 110 has a resonance at a first frequency that varies in response to changes in the temperature of the temperature sensor. Temperature measurement circuit 120 is to generate a temperature signal TS dependent on the first frequency. Variable RF power source 130 is to deliver to temperature sensor 110 a controlled level of RF power at a second frequency corresponding to a resonance of temperature sensor 110, and is additionally to output a power monitoring signal PM that provides a measure of the RF power delivered by variable RF power source 130 to temperature sensor 110. Power controller 140 operates in response to temperature signal TS to control the level of the RF power delivered by variable RF power source 130 to temperature sensor 110 to maintain temperature signal TS constant notwithstanding variations in external power input to temperature sensor 110.

In the example shown in FIG. 1, temperature sensor 110 includes a quartz blank 112 sandwiched between electrodes 114, 116. Electrode 114 is connected to diplexer 160 and electrode 116 is connected to signal ground. Quartz blank 112 includes an electromechanically-resonant quartz crystal having at least one resonance at a frequency that will be referred to as a first frequency f₁. A quartz crystal suitable for use in temperature sensor 110 is quartz crystal in which the resonance at first frequency f₁ is temperature dependent to an extent that allows the temperature of the quartz crystal to be determined accurately and conveniently by measuring the frequency of the resonance, or by measuring another parameter, such as impedance or phase, that depends on the frequency of the resonance at first frequency f₁. In an example, the quartz crystal is a Y-cut quartz crystal having a resonance at a single frequency (frequency f₁). In another example, the quartz crystal is an SC-cut quartz crystal having resonances at two frequencies. The one of the resonances at frequency f₁ (that of the B mode) has a substantially larger temperature coefficient than the other of the resonances (that of the C mode). Quartz crystals may have resonances in addition to those described above, but such additional resonances are not useful because they are substantially lower in Q than the resonances described above, and will therefore be ignored.

In another example, temperature sensor 110 includes an electromechanically-resonant film bulk acoustic resonator (FBAR) having a series resonance and a parallel resonance at different frequencies, one of which is frequency f₁. However, the series and parallel resonances differ insufficiently in frequency for an FBAR to be regarded as having resonances at two different frequencies, one of which is frequency f₁. An FBAR suitable for use as temperature sensor 110 is an FBAR in which the resonance at frequency f₁ is temperature dependent to an extent that allows the temperature of the FBAR to be determined accurately and conveniently by measuring the frequency of the resonance at frequency f₁, or by measuring another parameter, such as impedance or phase, that depends on the frequency of the resonance at first frequency f₁.

Temperature sensor 110 is typically thermally coupled to a receptor for the power or heat to be measured. In an example, temperature sensor 110 is thermally coupled at the periphery of quartz blank 112 to a thin membrane of a thermally-conductive material in a manner that allows the center of the temperature sensor to vibrate independently of the membrane. In an example, the material of the membrane is silicon nitride (Si₃N₄). To measure optical power, the membrane is coated with an optically-absorbing material, or has an optically-absorbing element affixed thereto. To measure microwave power, the membrane is coated with a microwave-absorbing material, or has a microwave-absorbing element or a termination resistor affixed thereto. In another example, reagents that produce an exothermic or endothermic reaction are placed on the membrane to enable the power measurement system to measure the heat generated by or absorbed by the reaction.

Temperature measurement circuit 120 is configured to generate a temperature signal TS in response to the resonance of temperature sensor 110 at the above-mentioned first frequency. A property of temperature signal TS, e.g., amplitude or frequency, or a digital value representing a property of temperature signal TS, depends on first frequency f₁, and, hence, on the temperature of temperature sensor 110. Temperature measurement circuit 120 is an active temperature measurement circuit. Temperature measurement circuit 120 includes a measurement signal output 122 at which it outputs a measurement signal MS to temperature sensor 110 via a first input port 162 and an output port 166 of diplexer 160. Temperature measurement circuit 120 outputs measurement signal MS at a frequency corresponding to the resonance of temperature sensor 110 at frequency f₁. In this disclosure, a signal having a frequency corresponding to a resonance is a signal nominally equal in frequency to the fundamental of a resonance, or nominally equal in frequency to an overtone of the resonance. A signal nominally equal in frequency to the fundamental of a resonance is a signal whose frequency is within the 3 dB bandwidth of the resonance. A signal nominally equal in frequency to an overtone of a resonance is a signal whose frequency is within the 3 dB bandwidth of the overtone. Signals whose frequencies within the 1 dB bandwidth of the fundamental of a resonance or an overtone of the resonance produce more optimum results.

Temperature measurement circuit 120 additionally includes a temperature signal output 124 at which it outputs temperature signal TS. Temperature measurement circuit 120 generates temperature signal TS by detecting changes in measurement signal MS caused by temperature-induced changes in the resonance of temperature sensor 110 at frequency f₁. Examples of temperature measurement circuit 120 will be described below with reference to FIGS. 2-4.

Variable RF power source 130 is coupled to temperature sensor 110 to deliver to the temperature sensor a controlled level of RF power CP at a second frequency f₂ that corresponds to a resonance of the temperature sensor, and is additionally to output a measure of the RF power delivered by variable RF power source 130 to the temperature sensor 110. In the example shown, variable RF power source 130 is coupled to deliver RF power to temperature sensor 110 via a second input port 164 and output port 166 of diplexer 160. The RF power delivered to temperature sensor 110 by variable RF power source 130 internally heats the temperature sensor to a set temperature higher than ambient temperature. Specifically, variable RF power source 130 delivers to temperature sensor 110 a controlled level of RF power sufficient to heat the temperature sensor to the set temperature notwithstanding heat loss from the temperature sensor to the ambient. Second frequency f₂ at which variable RF power source 130 delivers RF power to temperature sensor 110 corresponds to the frequency of a resonance of the temperature sensor to ensure that the RF power is efficiently coupled to the temperature sensor.

Variable RF power source 130 includes an RF power output 132 at which the variable RF power source outputs controlled level of RF power CP. RF power output 132 is coupled to temperature sensor 110 via the second input port 164 and output port 166 of diplexer 160. Variable RF power source 130 additionally includes a power monitoring output 134 via which the variable RF power source outputs a power monitoring signal PM that represents the power output by variable RF power source 130 at RF power output 132, and hence provides a measure of the RF power delivered by variable RF power source 130 to temperature sensor 110. In the example shown, variable RF power source 130 outputs power monitoring signal PM to optional power measurement circuit 150. The level of RF power CP delivered to temperature sensor 110 by variable RF power source 130 is controlled by power control signal PC received from power controller 140 at power control input 136. Examples of variable RF power source 130 will be described below with reference to FIGS. 6-9.

In embodiments in which temperature sensor 110 has a single resonance, the second frequency f₂ at which variable RF power source 130 delivers RF power CP to temperature sensor 110 is nominally equal to the frequency f₁ of the fundamental of the single resonance or to the frequency of an overtone of the single resonance. In embodiments in which temperature sensor 110 has a first resonance at frequency f₁ and a second resonance at a frequency different from that of the first resonance, the second frequency f₂ at which the variable RF power source delivers RF power to temperature sensor 110 is nominally equal to the frequency of the fundamental of the second resonance, or to the frequency of an overtone of the second resonance.

Power controller 140 has a temperature signal input 142, and a power control signal output 144. In the example shown, power controller 140 additionally has a temperature set input 146 at which power controller 140 receives an external temperature set signal SET. Temperature set signal SET defines the set temperature, higher than ambient temperature, at which the RF power delivered by variable RF power source 130 maintains temperature sensor 110. In another example, power controller 140 generates temperature set signal SET internally, and lacks a temperature set input. Power controller 140 operates in response to temperature signal TS received at temperature signal input 142 and in response to temperature set signal SET to generate power control signal PC. Power controller 140 outputs power control signal PC at power control signal output 144 to control the level of the RF power delivered by variable RF power source 130 to temperature sensor 110. Power control signal PC controls the level of RF power to maintain temperature sensor 110 at a constant set temperature notwithstanding variations in external power input to the temperature sensor temperature. Temperature signal TS provides a measure of the temperature of temperature sensor 110 determined from the resonance of the temperature sensor at first frequency f₁. Thus, a constant temperature signal TS is indicative of a constant temperature of temperature sensor 110.

Power controller 140 detects any variation in temperature signal TS caused by a change in the temperature of temperature sensor 110 due, for example, a variation in ambient temperature, or due to the input of external power to the temperature sensor. In response, to the variation in temperature signal TS, power controller 140 changes power control signal PC in a manner that causes variable RF power source 130 to change the level of RF power delivered to the temperature sensor in a way that corrects the temperature variation of the temperature sensor. For example, when the temperature of the temperature sensor increases due to an increase in ambient temperature, power control signal PC causes variable RF power source 130 to reduce the level of RF power delivered to the temperature sensor by an amount that restores the temperature of the temperature sensor to its set temperature, and thus restores temperature signal TS to its original state. Temperature sensor 110 is typically located in a temperature-controlled enclosure to minimize variations in ambient temperature.

Power controller 140 operates in a way similar to that just described when external power is input to temperature sensor 110. Such external power causes the temperature of temperature sensor 110 to increase, and temperature signal TS to change in a manner consistent with an increased temperature of temperature sensor 110. The change in temperature signal TS causes power controller 140 to change power control signal PC in a manner that causes variable RF power source 130 to reduce the level of RF power delivered to the temperature sensor in a way that corrects the temperature variation of the temperature sensor. This restores temperature sensor 110 to its set temperature. The measured reduction in the level of RF power delivered by variable RF power source 130 to temperature sensor 110 is equal to the external power input to the temperature sensor.

In applications in which power measurement system 100 is to measure external heat input to temperature sensor 110 instead of external power, the measured reductions in the RF power delivered to temperature sensor 110 during the time during in the external heat is input to the temperature sensor are summed to quantify the external heat input to the temperature sensor.

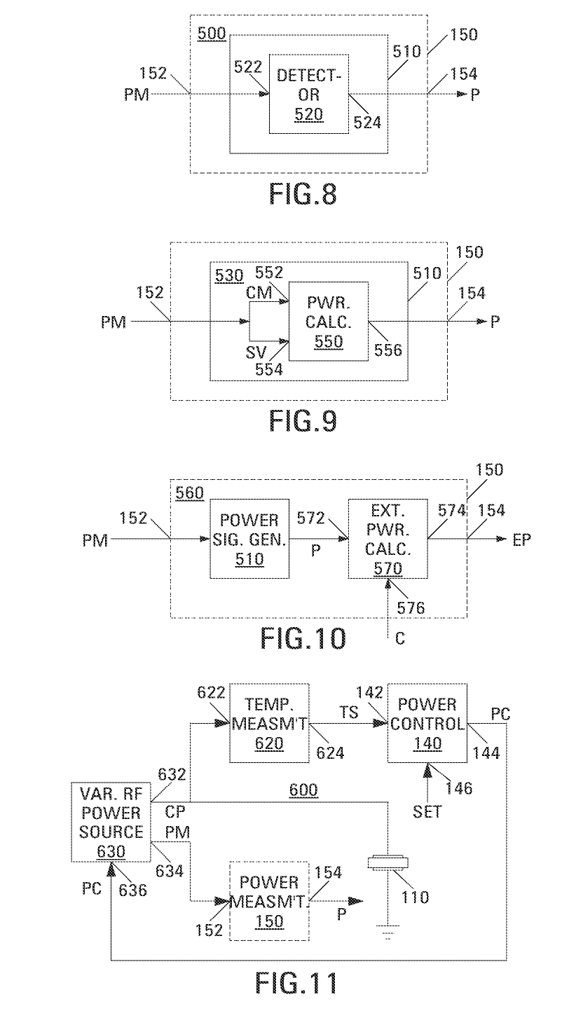

Optional power measurement circuit 150 includes an input 152 and an output 154. Input 152 is connected to receive power monitoring signal PM from the power monitoring output 134 of variable RF power source 130. Power measurement circuit 150 measures the level of RF power represented by power monitoring signal PM to generate a measured power signal P. In simple embodiments, measured power signal P represents the level of the RF power output by variable RF power source 130 to temperature sensor 110. In such embodiments, the external power input to the temperature sensor can be calculated from measured power signal P. In more complex embodiments, measured power signal P directly represents the external power input (and in some example, the external heat input) to the temperature sensor. Examples of power measurement circuit 150 will be described in detail below with reference to FIGS. 8-10.

Some embodiments of diplexer 160 include a high-pass filter connected between one of input ports 162, 164 and output port 166, and a low-pass filter connected between the other of input ports 162, 164 and output port 166. Whether the high-pass filter is connected to input port 162 or to input port 164 depends on whether the frequency of measurement signal MS is higher than or lower than, respectively, second frequency f₂.

Examples of the elements of power measurement system 100 will now be described. In an embodiment of power measurement system 100, temperature sensor 110 includes an SC-cut quartz crystal. An SC-cut quartz crystal has two resonances referred to as a mode B resonance and a mode C resonance. The frequency of the fundamental of the mode B resonance is about 9.4% higher than that of the mode C resonance. The frequency of the fundamental of the mode B resonance has a nearly linear temperature coefficient of −25.5 parts per million per degree C (ppm/° C.), whereas the frequency of the fundamental of the mode C resonance has a cubic temperature coefficient that is much less than 1 ppm/° C. In an SC-cut quartz crystal, the mode B resonance and the mode C resonance are mechanically orthogonal, and are therefore unlikely to interact due to nonlinearities in the quartz crystal.

In an embodiment of power measurement system 100 in which temperature sensor 110 includes an SC-cut quartz crystal, first frequency f₁, in response to which temperature measurement circuit 120 generates temperature signal TS, corresponds to the frequency of the fundamental of the mode B resonance of the SC-cut quartz crystal, whereas second frequency f₂ at which variable RF power source 130 delivers RF power to temperature sensor 110 corresponds to the frequency of the fundamental of the mode C resonance of the SC-cut quartz crystal. The larger temperature coefficient of the frequency of the fundamental of the mode B resonance translates variations in the temperature of temperature sensor 110 into easily-detectable variations in temperature signal TS, whereas the smaller temperature coefficient of the frequency of the fundamental of the mode C resonance ensures that variations in the temperature of temperature sensor 110 negligibly change the matching between the frequency of variable RF power source 130 and the frequency of the fundamental of the mode C resonance of the temperature sensor or the frequency of an overtone of the mode C resonance.

In a first example of power measurement system 100 in which temperature sensor 110 includes an SC-cut quartz crystal, first frequency f₁ is nominally equal to the frequency of the fundamental of the mode B resonance, and second frequency f₂ is nominally equal to the frequency of the fundamental of the mode C resonance. In an example in which the frequency of the fundamental of the mode B resonance of temperature sensor 110 is 193 MHz, and that of the mode C resonance is 180 MHz, first frequency f₁ is nominally equal to 193 MHz, and second frequency f₂ is nominally equal to 180 MHz.

In the first example of power measurement system 100 in which temperature sensor 110 includes an SC-cut quartz crystal as just described, the relatively small difference (9.4%) in frequency between the fundamentals of the mode B and mode C resonances of the temperature sensor makes the design of diplexer 160 challenging. The design of diplexer 160 can be simplified by making at least one of the frequencies f₁ and f₂ nominally equal to the frequency of an overtone of the corresponding resonance of the temperature sensor.

In a second example of power measurement system 100 in which temperature sensor 110 includes an SC-cut quartz crystal, first frequency f₁ is nominally equal to the frequency of an overtone of the mode B resonance, and second frequency f₂ is nominally equal to the frequency of the fundamental of the mode C resonance. In an example, first frequency f₁ is nominally equal to 3×193 MHz=579 MHz, corresponding to the third overtone of the mode B resonance, and second frequency f₂ is nominally equal to 180 MHz, corresponding to the fundamental of the mode C resonance. The greater than two-octave frequency difference between first frequency f₁ and second frequency f₂ in this example substantially simplifies the design of diplexer 160.

In a third example of power measurement system 100 in which temperature sensor 110 includes an SC-cut quartz crystal, first frequency f₁ is nominally equal to the frequency of the fundamental of the mode B resonance, and second frequency f₂ is nominally equal to the frequency of an overtone of the mode C resonance. In an example, first frequency f₁ is nominally equal to 193 MHz and second frequency f₂ is nominally equal to 3×180 MHz=540 MHz. Again, the large frequency difference between first frequency f₁ and second frequency f₂ resulting from making one of the frequencies f₁ and f₂ correspond to the frequency of an overtone of one of the resonances of the SC-cut quartz crystal simplifies the design of diplexer 160.

In a fourth example of power measurement system 100 in which temperature sensor 110 includes an SC-cut quartz crystal, first frequency f₁ is nominally equal to the frequency of an overtone of the mode B resonance, and second frequency f₂ is nominally equal to the frequency of a different overtone of the mode C resonance. In an example, first frequency f₁ is nominally equal to 3×193 MHz=579 MHz, corresponding to the third overtone of the mode B resonance, and second frequency f₂ is nominally equal to 5×180 MHz=900 MHz, corresponding to the fifth overtone of the mode C resonance. The large frequency difference between first frequency f₁ and second frequency f₂ in this example simplifies the design of diplexer 160.

In another embodiment of power measurement system 100, temperature sensor 110 includes a Y-cut quartz crystal. A Y-cut quartz crystal has a single resonance having a nearly linear temperature coefficient of approximately +85 ppm/° C. In an embodiment of power measurement system 100 in which temperature sensor 110 includes a Y-cut quartz crystal, at least one of first frequency f₁, in response to which temperature measurement circuit 120 generates temperature signal TS, and second frequency f₂ at which variable RF power source 130 delivers RF power CP to temperature sensor 110, corresponds to the frequency of an overtone of the resonance of the Y-cut quartz crystal. The other of first frequency f₁ and second frequency f₂ corresponds to the frequency of the fundamental of the resonance of the Y-cut quartz crystal or to the frequency of a different overtone of the resonance.

A Y-cut quartz crystal has a substantial temperature coefficient, so that changes in the temperature of temperature sensor 110 can cause a temperature-induced mismatch between the frequency f₂ at which variable RF power source 130 delivers RF power to temperature sensor 110 and the frequency of the fundamental or the overtone of the resonance of the temperature sensor. However, such a mismatch would only be problematic at startup since, once temperature sensor 110 reaches its set temperature, temperature measurement circuit 120, power controller 140, and the controlled level of RF power from variable RF power source 130 maintain temperature sensor 110 at a constant temperature.

In a first example of power measurement system 100 in which temperature sensor 110 includes a Y-cut quartz crystal, first frequency f₁ is nominally equal to the frequency of an overtone of the resonance of the Y-cut quartz crystal, and second frequency f₂ is nominally equal to the frequency of the fundamental of the resonance of the Y-cut quartz crystal. In an example in which the frequency of the fundamental of the resonance of the Y-cut quartz crystal is 200 MHz, first frequency f₁ is nominally equal to 3×200 MHz=600 MHz, corresponding to the third overtone of the resonance, and second frequency f₂ is nominally equal to 200 MHz, corresponding to the fundamental of the resonance. The greater than one-octave frequency difference between first frequency f₁ and second frequency f₂ in this example simplifies the design of diplexer 160.

In a second example of power measurement system 100 in which temperature sensor 110 includes a Y-cut quartz crystal, first frequency f₁ is nominally equal to the frequency of the fundamental of the resonance of the Y-cut quartz crystal, and second frequency f₂ is nominally equal to the frequency of an overtone of the resonance of the Y-cut quartz crystal. In an example, first frequency f₁ is nominally equal to 200 MHz and second frequency f₂ is nominally equal to 3×200 MHz=600 MHz. Again, the large frequency difference between first frequency f₁ and second frequency f₂ resulting from making one of the frequencies f₁ and f₂ correspond to the frequency of an overtone of the resonance of the Y-cut quartz crystal simplifies the design of diplexer 160.

In a third example of power measurement system 100 in which temperature sensor 110 includes a Y-cut quartz crystal, first frequency f₁ is nominally equal to the frequency of an overtone of the resonance of the Y-cut quartz crystal, and second frequency f₂ is nominally equal to the frequency of a different overtone of the resonance of the Y-cut quartz crystal. In an example, first frequency f₁ is nominally equal to 3×200 MHz=600 MHz, corresponding to the third overtone of the resonance, and second frequency f₂ is nominally equal to 5×200 MHz=1,000 MHz, corresponding to the fifth overtone of the resonance. The large frequency difference between first frequency f₁ and second frequency f₂ in this example simplifies the design of diplexer 160.

Quartz crystals having other cuts with appreciable and predictable temperature coefficients can be used in other implementations of power measurement system 100.

FIG. 2 is a schematic diagram showing an example 200 of temperature measurement circuit 120. Temperature measurement circuit 200 includes an oscillator circuit 210 and a frequency measuring circuit 230. Only the AC components of oscillator circuit 210 are shown to simplify the drawing. Temperature sensor 110 is coupled via diplexer 160 (FIG. 1) and measurement signal output 122 to oscillator circuit 210. The temperature-dependent frequency of the resonance of temperature sensor 110 at frequency f₁, or the frequency of an overtone of such resonance, determines the frequency at which oscillator circuit 210 oscillates. Thus, the frequency at which oscillator circuit 210 oscillates provides a measure of the temperature of temperature sensor 110.

Oscillator circuit 210 includes a transistor 212. The emitter of transistor 212 is connected to the measurement signal output 122 of temperature measurement circuit 120. Measurement signal output 122 is in turn coupled via diplexer 160 (FIG. 1) to temperature sensor 110. An inductor 214 is connected between collector and base of transistor 212, and the base of transistor 212 is connected to signal ground through a capacitor 216. Inductor 214 and the combination of capacitors 216, 218, and 220 form a series resonant circuit having a resonance at a frequency nominally equal to first frequency f₁, i.e., the frequency of the fundamental of the resonance or one of the resonances of temperature sensor 110, or the frequency of an overtone of such resonance or one of such resonances. Transistor 212 provides gain that causes oscillator circuit 210 to oscillate.

Additionally connected to the collector of transistor 212 is a capacitive voltage divider formed by capacitors 218 and 220, in which the capacitance of capacitor 220 is substantially larger than that of capacitor 218. Frequency measuring circuit 230 has an input 232 and an output 234. Input 232 is connected to the node between capacitors 218 and 220. Output 234 is connected to the temperature signal output 124 of temperature measurement circuit 120. Frequency measuring circuit 230 measures the frequency at which oscillator circuit 210 oscillates to generate temperature signal TS.

In an example, frequency measuring circuit 230 includes a frequency counter (not separately shown) that generates temperature signal TS as a digital signal having a value or an analog signal having a level (or other property) that represents the frequency of oscillator circuit 210. In another example, frequency measuring circuit 230 includes an analog frequency measuring circuit (not separately shown) that generates temperature signal TS as an analog signal having a level (or other property) represents the frequency of oscillator circuit 210. Optionally, an analog-to-digital converter is used to convert the analog temperature signal to a digital temperature signal. Other circuits capable of generating temperature signal TS as an analog signal having a property that represents the frequency of oscillator circuit 210 or capable of generating temperature signal TS as a digital signal having a value that represents the frequency of oscillator circuit 210 may be used as frequency measuring circuit 230.

In some embodiments, frequency measuring circuit 230 is part of a frequency counter instrument (not shown) external to power measurement system 100. In such embodiments, temperature measurement circuit 200 includes two connectors (not shown) that allow the input of the external frequency counter instrument to be connected to the node between capacitors 218, 220, and the output of the external frequency counter instrument to be connected to temperature signal output 124.

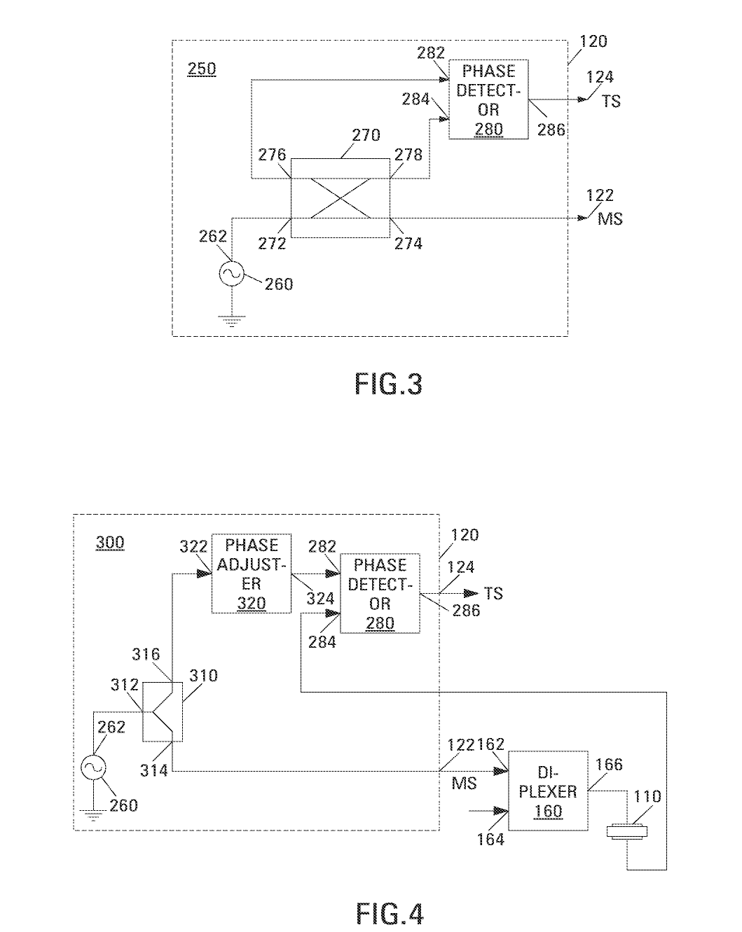

FIG. 3 is a schematic diagram showing another example 250 of temperature measurement circuit 120. Temperature measurement circuit 250 includes an oscillator 260, a directional coupler 270 and a phase detector 280. Oscillator 260 is a highly-temperature stable oscillator that generates an RF signal at a frequency nominally equal to the frequency of the fundamental of the resonance of temperature sensor 110 at first frequency f₁, or the frequency of an overtone of such resonance. Oscillator 260 has a signal output 262.

Directional coupler 270 has a first port 272, a second port 274, a third port 276, and a fourth port 278. First port 272 is connected to the signal output 262 of oscillator 260. Second port 274 is connected to the measurement signal output 122 of temperature measurement circuit 250.

Phase detector 280 has inputs 282, 284 and an output 286. Inputs 282, 284 are connected to the third port 276 and the fourth port 278, respectively, of directional coupler 270. The output 286 of phase detector 280 is connected to the temperature signal output 124 of temperature measurement circuit 250.

In operation of temperature measurement circuit 250, directional coupler 270 couples a sample of the RF output signal of oscillator 260 received at first port 272 to fourth port 278, and couples a sample of measurement signal MS from temperature sensor 110 (FIG. 1) received at second port 274 to third port 276. Phase detector 280 measures the phase difference between the sample of the RF output signal of oscillator 260 and the sample of measurement signal MS from temperature sensor 110 to generate temperature signal TS. The phase difference changes depending on the relationship between the temperature-dependent resonant frequency of temperature sensor 110 and the temperature-independent frequency of the RF output signal of oscillator 260.

FIG. 4 is a schematic diagram showing another example 300 of temperature measurement circuit 120. FIG. 4 additionally shows diplexer 160 and temperature sensor 110 of power measurement system 100 to show connections to temperature sensor 110 in this example. Elements of temperature measurement circuit 300 that correspond to elements of temperature measurement circuit 250 described above with reference to FIG. 3 are indicated using the same reference numerals and will not be described again in detail. Temperature measurement circuit 300 includes oscillator 260, phase detector 280, a signal splitter 310 and a phase adjuster 320.

Signal splitter 310 has an input port 312 and two output ports 314, 316. Input port 312 is connected to the output 262 of oscillator 260. Output port 314 is connected to electrode 114 of temperature sensor 110.

Phase adjuster 320 has an input 322 and an output 324. Input 322 is connected to output port 316 of signal splitter 310 and output 324 is connected to input 282 of phase detector 280. Input 284 of phase detector 280 is connected to electrode 116 of temperature sensor 110.

In operation of temperature measurement circuit 300, signal splitter 310 outputs a portion of the RF signal output by oscillator 260 at output port 314 and the remainder of the RF signal at output port 316. The portion of the RF signal output at output port 314 passes through diplexer 160 and temperature sensor 110 to the input 284 of phase detector 280. Phase adjuster 320 applies a temperature-independent phase shift to the portion of the RF signal output at output port 316 of signal splitter 310 substantially equal to the total phase shift imposed on the portion of the RF signal output at output port 314 by diplexer 160 and temperature sensor 110 at its set temperature. Phase detector 280 measures the phase difference between the portion of the RF signal output at output port 314 of signal splitter 310 and the portion of the RF signal output at output port 316 to generate temperature signal TS. The phase difference changes depending on the relationship between the temperature-dependent resonant frequency of temperature sensor 110 and the temperature-independent frequency of the RF signal generated by oscillator 260.

Other circuits capable of generating temperature signal TS depending on the temperature-dependent resonant frequency of temperature sensor 110 can be used as temperature measurement circuit 120.

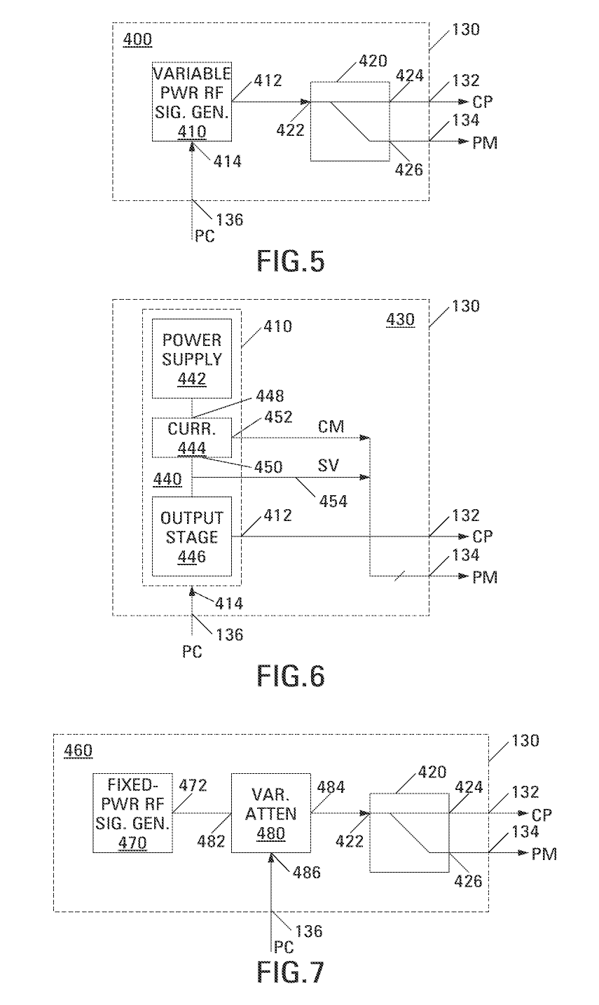

FIG. 5 is a block diagram showing an example 400 of variable RF power source 130. Variable RF power source 400 includes an internal variable-power RF signal generator 410 and a coupler 420. Variable-power RF signal generator 410 includes an RF output 412 and a power control input 414. Coupler 420 includes a power input 422, a power output 424 and a monitoring output 426. The power control input 414 of variable-power RF signal generator 410 is connected to receive power control signal PC from the power control input 136 of variable RF power source 400. The RF output 412 of variable-power RF signal generator 410 is connected to the power input 422 of coupler 420. The power output 424 of coupler 420 is connected to the RF power output 132 of variable RF power source 400. The monitoring output 426 of coupler 420 is connected to the power monitoring output 134 of variable RF power source 400.

Variable-power RF signal generator 410 outputs RF power at RF output 412 at frequency f₂, corresponding to a resonance of temperature sensor 110 (FIG. 1). The power level of the RF power output by variable-power RF signal generator 410 is controlled by power control signal PC received at power control input 414. Coupler 420 outputs most of the RF power output by the variable-power RF signal generator 410 at power output 132 as RF power CP, and outputs a sample of the RF power received from variable-power RF signal generator 410 at power monitoring output 134 as power monitoring signal PM. Power monitoring signal PM provides a measure of the RF power delivered by variable RF power source 400 to temperature sensor 110.

In another example of variable RF power source 400 that may be used as variable RF power source 130, an external variable-power RF signal generator (not shown) is substituted for internal variable-power RF signal generator 410. In such an embodiment, the variable RF power source includes a connector (not shown) to receive the variable level of RF power at second frequency f₂ from the external variable-power RF signal generator and a connector (not shown) to output power control signal PC to the external variable-power RF signal generator. In yet another example of variable RF power source 400 that may be used as variable RF power source 130, an external variable-power RF signal generator (not shown) and an external coupler connected in series are substituted for internal variable-power RF signal generator 410 and internal coupler 420. In such an embodiment, the variable RF power source includes a connector (not shown) to receive the variable level of RF power at frequency f₂ from the power output of the external coupler, a connector (not shown) to receive power monitoring signal PM from the external coupler, and a connector (not shown) to output power control signal PC to the external variable-power RF signal generator.

FIG. 6 is a block diagram showing another example 430 of variable RF power source 130. Variable RF power source 430 includes an embodiment 440 of internal variable-power RF signal generator 410 configured to generate a power monitoring signal PM that represents the DC power supplied to the output stage of variable-power RF signal generator 440. In the example shown, variable-power RF signal generator 440 includes a power supply 442, a current measuring circuit 444, and an output stage 446. Other elements of variable-power RF signal generator 440 are not shown to simplify the drawing. Output stage 446 provides the variable level of RF power generated by variable-power RF signal generator 440 to the RF output 132 of variable RF power source 130 as RF power CP.

Current measuring circuit 444 has a current input 448, a current output 450 and a current measurement output 452. Current input 448 is connected to power supply 442 and current output 450 is connected to a current input of output stage 446. Current measuring circuit 444 measures the current input to output stage 446 to generate a current measurement signal CM. Additionally, a conductor 454 conveys a supply voltage signal SV from the power supply input of output stage 444. Current measurement signal CM and supply voltage signal SV collectively constitute power monitoring signal PM and are output at the power monitoring output 134 of variable RF power source 130.

In embodiments of variable RF power source 430 in which the output voltage of power supply 442 is well-defined, only current measurement signal CM is output as power monitoring signal PM. In embodiments of variable RF power source 430 in which power control signal PC received at power control input 136 varies the output voltage of power supply 442 to control the power output by variable RF power source 430, and in which the relationship between the output voltage of power supply 442 and the level of RF power output by variable RF power source 430 is well-defined, current measuring circuit 444 is omitted, and only supply voltage signal SV is output as power monitoring signal PM.

In another example of variable RF power source 430 that can be used as variable RF power source 130, an external variable-power RF signal generator (not shown) similar in structure to variable-power RF signal generator 440 is substituted for internal variable-power RF signal generator 440 and the variable RF power source includes appropriate connectors (not shown) to receive the RF power output and power monitoring signal PM from, and to provide power control signal PC to, the external variable-power RF signal generator.

FIG. 7 is a block diagram showing another example 460 of variable RF power source 130. Elements of variable RF power source 460 that correspond to elements of variable RF power source 400 described above with reference to FIG. 5 are indicated using the same reference numerals and will not be described again in detail. Variable RF power source 460 includes an internal fixed-power RF signal generator 470, a variable attenuator 480 and coupler 420.

Fixed-power RF signal generator 470 has an RF power output 472. Variable attenuator 480 has a power input 482, a power output 484 and an attenuation control input 486. Power input 482 is connected to the RF power output 472 of fixed-power RF signal generator 470. Power output 484 is connected to the power input 422 of coupler 420. Attenuation control input 486 is connected to receive power control signal PC from the power control input 136 of variable RF power source 130. The power output 424 of coupler 420 is connected to the RF power output 132 of variable RF power source 130, and the monitoring output 426 of coupler 420 is connected to power monitoring output 134.

Fixed-power RF signal generator 470 outputs at RF output 472 a fixed level of RF power at frequency f₂ corresponding to the frequency of a resonance of temperature sensor 410 (FIG. 1). Variable attenuator 480 subjects the RF power output by fixed-power RF signal generator 470 to an attenuation defined by power control signal PC received at attenuation control input 486 to output RF power at output 484 at a power level controlled the power control signal. Coupler 420 outputs most of the RF power output by variable attenuator 480 to RF power output 132, and outputs a sample of the RF power received from variable attenuator 480 at power monitoring output 134 as power monitoring signal PM, in a manner similar to that described above.

In other examples of variable RF power source 460 that may be used as variable RF power source 130, an external fixed-power RF signal generator (not shown) is substituted for internal fixed-power RF signal generator 470, or an external fixed-power RF signal generator (not shown) and an external variable attenuator (not shown) are substituted for internal fixed-power RF signal generator 470 and internal variable attenuator 480, or an external fixed-power RF signal generator (not shown), an external variable attenuator (not shown), and an external coupler (not shown) are substituted for internal fixed-power RF signal generator 470, internal variable attenuator 480, and internal coupler 420. In such examples, the variable RF power source includes appropriate connectors (not shown) to receive signals from, and to provide signals to, the external components.

Examples of power measurement circuit 150 will now be described. FIG. 8 is a block diagram showing an example 500 of power measurement circuit 150. Power measurement circuit 500 includes a measured power signal generator 510 that generates measured power signal P in response to power monitoring signal PM. In power measurement circuit 500, measured power signal generator 510 includes a detector 520 that detects RF power monitoring signal PM output by the examples of variable RF power source 130 described above with reference to FIGS. 5 and 7 to generate measured power signal P. Detector 520 has an input 522 connected to the input 152 of power measurement circuit 500, and an output 524 connected to the output 154 of power measurement circuit 500.

In some implementations, detector 520 additionally includes circuitry to linearize the relationship between the level of power monitoring signal PM output by variable RF power source 130 (FIG. 1) and the level of measured power signal P. In some implementations, measured power signal generator 510 additionally includes an analog-to-digital converter (not shown) connected to the output of detector 520 to convert the analog measured power signal P generated by detector 520 to a digital power measurement signal.

FIG. 9 is a block diagram showing another example 530 of power measurement circuit 150.

Power measurement circuit 530 includes measured power signal generator 510 that generates measured power signal P in response to power monitoring signal PM. In power measurement circuit 530, measured power signal generator 510 includes a power calculation circuit 550 configured to generate measured power signal P from the DC power monitoring signal PM output by the example of variable RF power source 130 described above with reference to FIG. 6.

Power calculation circuit 550 includes a current input 552, a voltage input 554 and a measured power output 556. Current input 552 and voltage input 554 are connected to receive the current measurement signal CM, and the supply voltage signal SV, respectively, that constitute power monitoring signal PM. Referring additionally to FIG. 6, power calculation circuit 550 multiplies current measurement signal CM received at current input 552 by supply voltage signal SV received at voltage input 554 and an efficiency factor that represents the efficiency (RF power output divided by DC power input) of output stage 446 to calculate the RF power output by variable RF power source 430 from the DC current and supply voltage input to output stage 446. In implementations in which the efficiency of output stage 446 varies with the DC current and/or supply voltage of the output stage, the efficiency factor applied by power calculation circuit 550 to calculate the RF output power is current and/or supply voltage dependent.

In embodiments of power calculation circuit 550 for use with an embodiment of variable RF power source 430 in which power control signal PC received at power control input 136 varies the supply current in output stage 446 to control the level of RF power output by variable RF power source 430, and in which the relationship between the level of RF power output by variable RF power source and the supply current to output stage 446 is well-defined, the voltage input 554 of power calculation circuit 550 can be omitted. In this case, power calculation circuit 550 calculates the level of RF power output by variable RF power source 430 using current measurement signal CM, and the defined relationship between supply current and level of RF power. In embodiments of power calculation circuit 550 for use with an embodiment of variable RF power source 430 in which power control signal PC received at power control input 136 varies the supply voltage output by power supply 442 to control the level of RF power output by variable RF power source 430, and in which the relationship between the supply voltage output by power supply 442 and the level of RF power output by variable RF power source 430 is well-defined, current measuring circuit the current input 552 of power calculation circuit 550 can be omitted. In this case, power calculation circuit 550 calculates the level of RF power output by variable RF power source 430 using supply voltage signal SV and the defined relationship between supply voltage SV and level of power output. In embodiments of power calculation circuit 550 for use with an embodiment of variable RF power source 430 in which the relationship between the level of RF power output by variable RF power source and power control signal PC is well-defined, power control signal PC is supplied to power calculation circuit 550 instead of current measurement signal CM and/or supply voltage signal SV. In this case, power calculation circuit 550 calculates the level of RF power output by variable RF power source 430 using power control signal PC, and the defined relationship between power control signal and level of RF power.

In some implementations, measured power signal generator 510 additionally includes an analog-to-digital converter connected to the output of power calculation circuit 550 to convert analog measured power signal P to a digital measured power signal.

In the examples of power measurement circuit 150 described above with reference to FIGS. 8 and 9, measured power signal P represents the level of RF power delivered to temperature sensor 110 by variable RF power source 130. To determine the external power received by power measurement system 100, the value or level of measured power signal P is read prior to power measurement system 100 receiving the external power, and is read again as the power measurement system receives the external power. The reading taken before the temperature sensor receives the external power is then subtracted from the reading taken as the temperature sensor receives the external power to determine the external power received by the temperature sensor. Each of the readings may be taken more than once.

FIG. 10 is a block diagram showing another example 560 of power measurement circuit 150 in which the above-described subtraction process is automated. Power measurement circuit 560 includes measured power signal generator 510 and an external power calculator 570 arranged in series. External power calculator has a measured power signal input 572, a measured external power signal output 574 and a control input 576. Measured power signal input 572 is connected to receive measured power signal P from measured power signal generator 510. Measured external power signal output 574 is connected to the output 154 of power measurement circuit 560. Control input 576 is connected to receive a control signal C that controls the operation of external power calculator 570.

The state of control signal C received at control input 576 indicates whether power measurement system 100 is receiving external power. Initially, the state of control signal C indicates that power measurement system 100 is not receiving external power. With control signal C in this state, external power calculator 570 receives and stores successive measured power signals P output by measured power signal generator 510. In response to a change in the state of control signal C, external power calculator subtracts at least one of the stored measured power signals from each subsequent measured power signal P received from measured power signal generator 510 to generate a measured external power signal EP that provides a measure of the external power received by power measurement system 100. In an example, the at least one stored measured power signal that external power calculator 570 subtracts from each measured power signal P is the last measured power signal received before control signal C changed state. In another example, the at least one stored measured power signal that external power calculator 570 subtracts from each measured power signal is the average or the median of the last N measured power signals received before control signal C changed state. Optionally, external power calculator 570 can receive and store measured power signals generated when power measurement system 100 is not receiving external power subsequent to receiving measured power signals generated when the power measurement system is receiving external power in addition to or instead of receiving and storing measured power signals generated when power measurement system 100 is not receiving external power prior to receiving measured power signals generated when the power measurement system.

Some embodiments of external power calculator 570 lack control input 576 and instead derive a control signal having a state that indicates whether power measurement system 100 is receiving external power by monitoring the measured power signals P received from power measurement circuit 500 to identify a reduction between consecutively-received measured power signals greater than a threshold reduction. Such a reduction indicates that power measurement system 100 is receiving external power.

Some embodiments of external power calculator 570 are configured to generate an external measured heat signal that provides a measure of external heat received by power measurement system 100 in addition to or instead of generating measured external power signal EP. In an example of such an embodiment, the external power calculator generates the measured external heat signal by summing successive levels or values of external measured power signal EP over the interval of time during which external heat is input to power measurement system 100.

In some implementations, an external power calculation instrument (not shown) is substituted for external power calculator 570, and power measurement circuit 560 includes suitable connectors to deliver signals to, and to receive signals from, the external power calculation instrument.

FIG. 11 is a block diagram showing another, simpler example 600 of a thermal substitution power measurement system. Power measurement system 600 uses the RF power delivered to the temperature sensor by the variable RF power source to determine the temperature of the temperature sensor. Elements of power measurement system 600 that correspond to elements of power measurement system 100 described above with reference to FIGS. 1-10 are indicated using the same reference numerals and will not be described again in detail. Power measurement system 600 includes temperature sensor 110, a temperature measurement circuit 620, a variable RF power source 630, and power controller 140. The example of power measurement system 600 shown in FIG. 11 additionally includes optional power measurement circuit 150

Temperature sensor 110 has a resonance at first frequency f₁ that depends on the temperature of the temperature sensor, as noted above. Temperature measurement circuit 620 is to generate a temperature signal TS dependent on the first frequency. The temperature measurement circuit is coupled to the temperature sensor. Variable RF power source 630 is to deliver to temperature sensor 110 a controlled level of RF power CP at a frequency corresponding to the resonance of temperature sensor 110, and is additionally to output a measure of the RF power delivered by the variable RF power source to the temperature sensor. Power controller 140 operates in response to temperature signal TS to control the level of the RF power delivered by variable RF power source 630 to temperature sensor 110 to maintain temperature signal TS constant notwithstanding variations in external power input to temperature sensor 110. Optional power measurement circuit 150 is to output a measured power signal P that provides a measure of the RF power delivered by variable RF power source 630 to temperature sensor 110.

Temperature measurement circuit 620 is a passive temperature measurement circuit that generates temperature signal TS by detecting changes in the controlled level of RF power CP output by variable RF power source 630 caused by temperature-induced changes in the resonance of temperature sensor 110.

Variable RF power source 630 is coupled to temperature sensor 110 to deliver to the temperature sensor a controlled level of RF power CP at a frequency corresponding to the first frequency, i.e., the frequency of the resonance of the temperature sensor. The frequency at which variable RF power source 630 delivers power to temperature sensor 110 is nominally equal to the frequency of the fundamental of the resonance of the temperature sensor at the first frequency, or is nominally equal to the frequency of an overtone of the resonance.

In the example shown, variable RF power source 630 has a power output 632, the power monitoring output 634 and a power control input 636. Power output 632 is connected to temperature sensor 110. The controlled level of RF power CP delivered by the variable RF power source 630 internally heats temperature sensor 110 to a set temperature higher than ambient temperature. Specifically, variable RF power source 630 delivers to temperature sensor 110 a controlled level of RF power CP sufficient to heat the temperature sensor to its set temperature notwithstanding heat loss from the temperature sensor to the ambient. The frequency at which variable RF power source 630 delivers RF power CP to the temperature sensor corresponds to the frequency of a resonance of the temperature sensor to ensure that the RF power is efficiently coupled to the temperature sensor.

Variable RF power source 630 additionally outputs power monitoring signal PM at power monitoring output 634. Power monitoring signal PM represents the power output by variable RF power source 630 at power output 632, and hence provides a measure of the RF power delivered by variable RF power source 630 to temperature sensor 110.

The RF output power delivered to temperature sensor 110 by variable RF power source 630 is controlled by power control signal PC received from power controller 140 at power control input 636.

Variable RF power sources that may be used as variable RF power source 630 include the examples of variable RF power source 130 described above with reference to FIGS. 5-7.

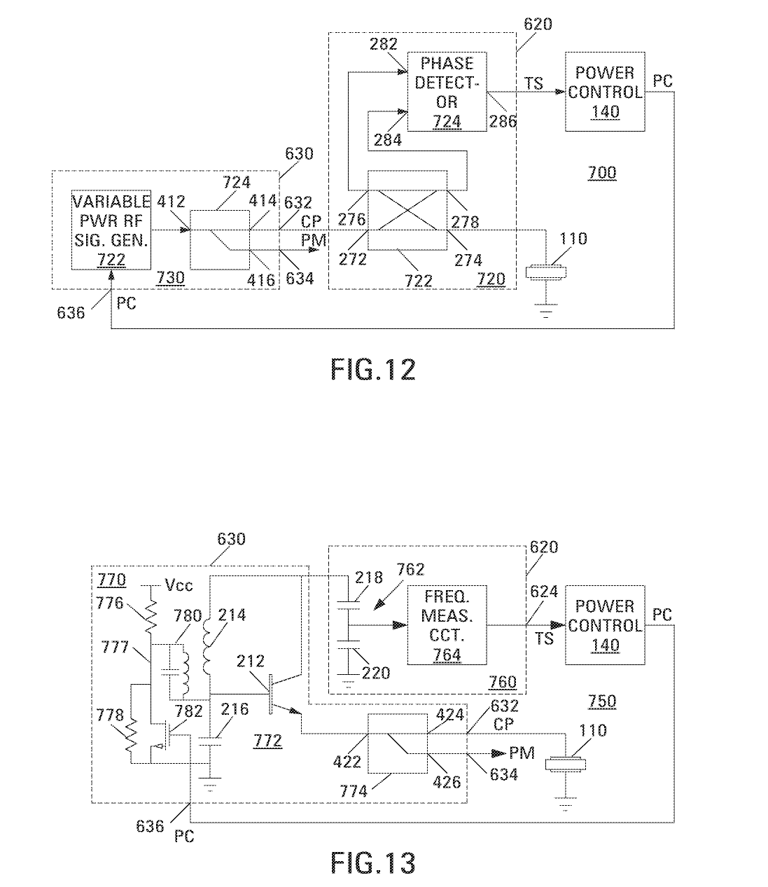

Examples of power measurement system 600 will now be described with reference to FIGS. 12-14. FIG. 12 is a block diagram showing an example 700 of power measurement system 600 in which passive temperature measurement circuit 620 generates temperature signal TS by measuring changes in the phase of the RF power delivered to temperature sensor 110 by variable RF power source 630 caused by temperature-induced changes in the resonance of the temperature sensor at a frequency corresponding to frequency f₁. Power measurement system 700 includes a temperature measurement circuit 720 and a variable RF power source 730. Temperature measurement circuit 720 includes a directional coupler 722 and a phase detector 724. Directional coupler 722 and phase detector 724 are implemented using directional coupler 270 and phase detector 280 described above with reference to FIG. 3. Temperature measurement circuit 720 generates temperature signal TS in response to changes in the phase of the RF power delivered to temperature sensor 110 by variable RF power source 730. Elements of directional coupler 722 and phase detector 724 that correspond to elements of directional coupler 270 and phase detector 280 are indicated using the same reference numerals and will not be described again in detail. In temperature measurement circuit 720, directional coupler 270 is interposed between the power output 632 of variable RF power source 630 and temperature sensor 110. Specifically, first port 272 and second port 274 of directional coupler 270 are connected to power output 632 and temperature sensor 110, respectively. Third port 276 and fourth port 278 of directional coupler 270 are connected to inputs 282, 284, respectively of phase detector 280. Output 286 of phase detector 280 supplies temperature signal TS to temperature signal output 624. Variations in the relationship between the temperature-dependent frequency of the resonance of temperature sensor 110 and the substantially temperature-independent frequency of the RF power output by variable RF power source 630 vary the phase of the power delivered to the temperature sensor. Directional coupler 270 couples such variations in phase to the inputs of phase detector 280. Phase detector 280 generates temperature signal TS in response to the variations in phase.

In the example of power measurement system 700 shown in FIG. 12, variable RF power source 730 is implemented using variable RF power source 400 described above with reference to FIG. 5. Elements of variable RF power source 730 that correspond to elements of variable RF power source 400 are indicated using the same reference numerals and will not be described again in detail. The variable RF power source implementations described above with reference to FIG. 6 and FIG. 7, or a different variable RF power source implementation, may be used as variable RF power source 630.

FIG. 13 is a schematic diagram showing an example 750 of power measurement system 600 in which the passive temperature measurement circuit generates temperature signal TS by measuring changes in the frequency of the RF power delivered to the temperature sensor by the variable power source caused by temperature-induced changes in the frequency of the resonance of the temperature sensor. In this example, the frequency of the resonance of the temperature sensor defines the frequency of the RF power output by the variable RF power source.

Power measurement system 750 shown in FIG. 13 includes a passive temperature measurement circuit 760 and a variable RF power source 770. Variable RF power source 770 includes an oscillator circuit 772 and a coupler 774. Oscillator circuit 772 is implemented as a higher-power version of oscillator 210 described above with reference to FIG. 2. Elements of oscillator circuit 772 that correspond to elements of oscillator circuit 210 are indicated using the same reference numerals and will not be described again. Some of the components of oscillator circuit 772 are omitted to simplify the drawing. The frequency of the resonance of temperature sensor 110 connected to power output 632 determines the frequency of oscillation of oscillator circuit 772. The frequency of oscillation may be the frequency of the fundamental of the resonance of the temperature sensor or the frequency of an overtone of the resonance.

In variable RF power source 770, the implementation of coupler 774 is similar to that of coupler 420 described above with reference to FIG. 5. Elements of coupler 774 that correspond to those of coupler 420 are indicated using the same reference numerals and will not be described again in detail. The emitter of transistor 212 is connected to the power input 422 of coupler 774. The power output 424 of coupler 774 is connected via the power output 632 of variable RF power source 770 to temperature sensor 110. Coupler 774 outputs power monitoring signal PM at monitoring output 426 connected to the monitoring output 634 of variable RF power source 770.

The level of RF power output by oscillator circuit 772 is determined by the current flowing through transistor 212. In oscillator circuit 772, a potential divider formed by resistors 776, 778 defines the base voltage of transistor 212 and, hence, the maximum current through transistor 212 and the maximum level of power output by variable RF power source 770. A node 777 between resistors 776, 778 is connected to the base of transistor 212 through a parallel resonant circuit 780 that isolates the base of transistor 212 from node 777 at the frequency of the resonance of temperature sensor 110. The drain and source of a transistor 782 is connected in parallel with resistor 776. The gate of transistor 782 is connected to receive power control signal PC from power control input 636.

Passive temperature measurement circuit 760 is implemented using a capacitive voltage divider 762 and a frequency measuring circuit 764. Capacitive voltage divider 762 is implemented using capacitors 218, 220 connected in series, as described above with reference to FIG. 2. Frequency measuring circuit 764 is implemented using frequency measuring circuit 230 described above with reference to FIG. 2. In the example shown, the input of capacitive divider 762 is connected to the collector of transistor 212 and the input the frequency measuring circuit 764 is connected to the node between capacitors 218 and 220 of capacitive voltage divider 762. In other examples, a single capacitor is substituted for capacitive voltage divider 762 and the input of frequency measuring circuit 764 is connected to the emitter of transistor 212, or to the main output port of coupler 774. Frequency measuring circuit 764 generates temperature signal TS in accordance with the frequency of the power generated by variable RF power source 770.

With temperature sensor 110 at its set temperature, the level of power control signal PC is such that transistor 782 is partially conducting. The additional current drawn by transistor 782 through resistor 776 reduces the voltage on the base of transistor 212 and, hence, the current through transistor 212 and the level of RF power output by variable RF power source 770, to less than maximum. A change in ambient temperature, or the input of external power to temperature sensor 110, changes the resonance of temperature sensor 110, which changes the frequency of the power output by variable RF power source 770. Temperature measurement circuit 720 changes temperature signal TS in response to the change in frequency measured by frequency measuring circuit 230. Power controller 140 changes power control signal PC in response to the change in temperature signal TS. The change in power control signal PC causes the current drawn by transistor 784 through resistor 776 to increase or decrease the base voltage of transistor 212 in a way that changes the output power of variable RF power source 770 to restore the temperature of temperature sensor 110 to the set temperature.

In another example, power control signal PC varies the power output of oscillator circuit 770 by varying the power supply voltage coupled to the collector of transistor 212.

Varying the power output of oscillator circuit 770 may result in the effect known as pulling, in which an incidental phase shift causes an offset between the frequency of oscillator circuit 770 and the frequency of the resonance of temperature sensor 110. Such an offset impairs the ability of the frequency of the oscillator to follow accurately the temperature-induced changes in the frequency of the resonance of temperature sensor 110. This effect can be mitigated by configuring oscillator circuit 770 to operate at the frequency of an overtone of the resonance of the temperature sensor. Higher overtones reduce the risk of pulling more than lower overtones or the fundamental. Further mitigation can be obtained by including temperature sensor 110 in a bridge stabilization circuit and using an error voltage developed by the bridge circuit to maintain a match between the frequency of the oscillator circuit and the resonant frequency of the temperature sensor notwithstanding changes in the temperature of the temperature sensor.

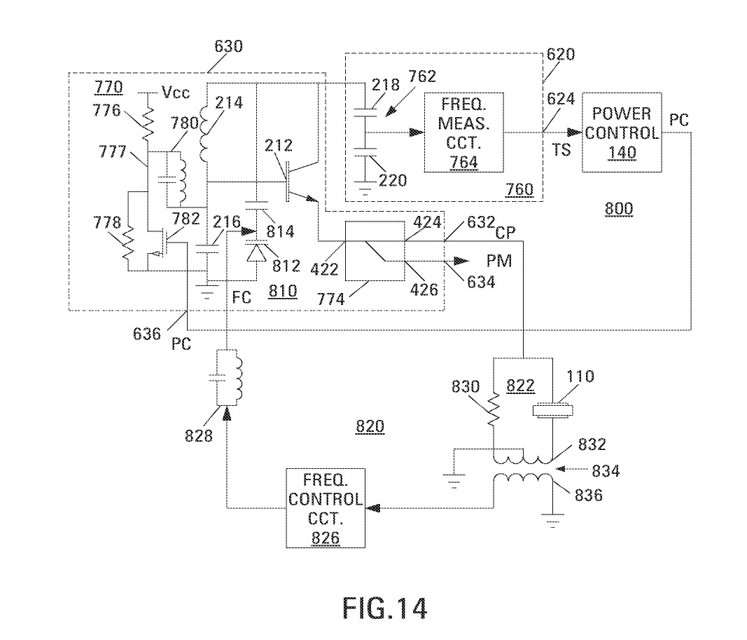

FIG. 14 is a schematic diagram showing an example 800 of power measurement system 600 in which the passive temperature measurement circuit measures changes in the frequency of the RF power CP generated by the oscillator circuit, and applies automatic frequency control to the oscillator circuit to match the frequency of the RF power to the frequency of the resonance of the temperature sensor. In power measurement system 800, variable RF power source 770 includes an oscillator circuit 810, and power measurement system 800 additionally includes a frequency control system 820 that controls the frequency of the RF power generated by oscillator circuit 810. Frequency control system 820 includes a bridge circuit 822 and a frequency control circuit 826. Frequency control system 820 generates a frequency control signal FC for oscillator circuit 810. Bridge circuit 822 is composed of temperature sensor 110, a resistor 830, and the primary winding 832 of a transformer 834. Temperature sensor 110 and resistor 830 respectively constitute adjacent first arms of the bridge circuit. Primary winding 832 has a center tap connected to ground. The halves of the primary winding respectively constitute adjacent second arms of the bridge circuit, opposite the first arms. The power output by oscillator circuit 810 is applied to a node of bridge circuit 822 between temperature sensor 110 and resistor 830. To balance bridge circuit 822, the resistance of resistor 830 is made equal to the equivalent series resistance of temperature sensor 110.

The secondary winding 836 of transformer 834 is connected to the input of frequency control circuit 826. The output of frequency control circuit 826 is connected via a parallel resonant circuit 828 to provide frequency control signal FC to oscillator circuit 810.

Oscillator circuit 810 is similar in structure to oscillator circuit 772 described above with reference to FIG. 13. Elements of oscillator circuit 810 that correspond to elements of oscillator circuit 772 are indicated using the same reference numerals and will not be described again in detail. Oscillator circuit 810 additionally includes a varactor diode 812 (the top of 814 should connect to the collector not the base) and a coupling capacitor 814, in series, connected between the collector of transistor 212 and ground. The capacitance of coupling capacitor 814 is large compared with the maximum capacitance of varactor diode 812. Frequency control signal FC is connected to the node between varactor diode 812 and coupling capacitor 814. Parallel resonant circuit 828 is resonant at the frequency of the RF power generated by oscillator circuit 810 with temperature sensor 110 at its set temperature to isolate varactor diode 812 from the output of frequency control circuit 826 at the frequency of the RF power. Frequency control signal FC applied to varactor diode 812 changes the capacitance of the parallel combination of varactor diode 812 and the series combination of capacitor 218 and capacitor 220. Hence, frequency control signal FC applied to varactor diode 812 changes the resonant frequency of the series resonant circuit composed of inductor 214 and the parallel combination of varactor diode 812 and the series combination of capacitor 218 and capacitor 220.

With no error signal received from bridge circuit 822, the frequency control signal FC output by frequency control circuit 826 sets the capacitance of varactor diode 812 to a value that matches the frequency of the RF power generated by oscillator circuit 810 to the frequency of the resonance of temperature sensor 110 at its set temperature.

Any mismatch between the frequency of the RF power generated by oscillator 810 and the frequency of the resonance of temperature sensor 110 due, for example, to the temperature of temperature sensor 110 increasing above the set temperature as a result of the temperature sensor receiving external power, causes an imbalance in bridge circuit 822. The imbalance in bridge circuit 822 appears in the primary winding 832 of transformer, and is coupled to the secondary winding 836 of the transformer. The imbalance generates an error signal in the secondary winding. The error signal output by secondary winding 836 is input to frequency control circuit 826. In response to the error signal, frequency control circuit 826 changes frequency control signal FC to a level that, when applied to varactor diode 812, forces the frequency of oscillator circuit 810 to track accurately the resonant frequency of temperature sensor 110 notwithstanding the perturbing influence of variable power control circuit 770. Frequency control system 820 is describing greater detail by Karlquist in U.S. Pat. No. 5,708,394.

This disclosure describes the invention in detail using illustrative embodiments. However, the invention defined by the appended claims is limited to the precise embodiments described.

I claim:

1. A thermal substitution power measurement system, comprising:
an electromechanically-resonant temperature sensor having a resonance at a first frequency, the first frequency varying in response to changes in temperature of the temperature sensor;
a temperature measurement circuit to generate a temperature signal dependent on the first frequency, the temperature measurement circuit coupled to the temperature sensor;
a variable RF power source to deliver to the temperature sensor a controlled level of RF power at a second frequency corresponding to a resonance of the temperature sensor, and additionally to output a measure of the RF power output by the variable RF power source; and
a power controller, operating in response to the temperature signal, to control the level of the RF power delivered to the temperature sensor by the variable RF power source, to maintain the temperature signal constant notwithstanding variations in external heat input to the temperature sensor.

2. The power measurement system of claim 1, in which the temperature sensor comprises a quartz crystal.

3. The power measurement system of claim 2, in which:
the quartz crystal is an SC-cut quartz crystal having a mode-B resonance and a mode-C resonance, each resonance having a respective frequency;
the first frequency corresponds to the frequency of the mode-B resonance; and
the second frequency corresponds to the frequency of the mode-C resonance.

4. The power measurement system of claim 3, in which at least one of the first frequency and the second frequency is the frequency of an overtone of the respective resonance.

5. The power measurement system of claim 2, in which:
the quartz crystal is a Y-cut quartz crystal having a single resonance;
the first frequency is nominally equal to the frequency of the fundamental of the single resonance; and
the second frequency is nominally equal to the frequency of an overtone of the single resonance.

6. The power measurement system of claim 2, in which:
the quartz crystal is a Y-cut quartz crystal having a single resonance;
the first frequency corresponds to the frequency of an overtone of the single resonance; and
the first frequency corresponds to the frequency of the fundamental of the single resonance.

7. The power measurement system of claim 1, in which the electromechanical resonator temperature sensor comprises a film bulk acoustic resonator (FBAR).

8. The power measurement system of claim 1, additionally comprising a power measurement circuit coupled to receive the measure of the RF power from the variable RF power source.

9. The power measurement system of claim 8, in which a difference between power measured by the power measurement circuit prior to the external power input and power measured by the power measurement circuit during the external power input provides a measure of the external power input.

10. The power measurement system of claim 1, in which the second frequency is different from the first frequency.

11. A power measurement system, comprising:
an electromechanically-resonant temperature sensor having a resonance at a first frequency, the first frequency dependent on temperature;
a passive temperature measurement circuit to generate a temperature signal dependent on the first frequency, the temperature measurement circuit coupled to the temperature sensor;
a variable RF power source connected to deliver to the temperature sensor a controlled level of RF power at a frequency corresponding to the first frequency, the variable RF power source additionally to output a measure of the RF power delivered by the variable RF power source to the temperature sensor; and
a power controller to control the level of the RF power delivered to the temperature sensor by the variable RF power source to maintain the temperature signal constant notwithstanding variations in external power input to the temperature sensor.

12. The power measurement system of claim 11, in which the temperature sensor comprises a quartz crystal.

13. The power measurement system of claim 11, in which the temperature sensor comprises a film bulk acoustic resonator (FBAR).

14. The power measurement system of claim 11, additionally comprising a power measurement circuit connected to the variable RF power source.

15. The power measurement system of claim 14, in which a difference between power measured by the power measurement circuit prior to the external power input and power measured by the power measurement circuit during the external power input provides a measure of the external power input.

16. The power measurement system of claim 11, in which:
the power measurement system additionally comprises:
a transformer comprising a secondary winding and a center-tap primary winding;
a bridge circuit electrically connected to the RF power source, and
a frequency control circuit to match the frequency of the RF power output by the variable RF power source to changes in the first frequency due to phase shifts caused by changes in the level of the RF power delivered by the variable RF power source;
the temperature sensor and a resistor constitute adjacent first arms of the bridge;
the center-tap primary winding of the of the transformer constitutes adjacent second arms of the bridge, opposite the first arms; and
the secondary winding of the transformer outputs an error signal to the frequency control circuit.

17. The power measurement system of claim 16, in which the temperature sensor comprises a quartz crystal.

18. The power measurement system of claim 16, in which the temperature sensor comprises a film bulk acoustic resonator (FBAR).

19. The power measurement system of claim 16, additionally comprising a power measurement circuit electrically connected to receive the measure of the RF power from the variable RF power source.

20. The power measurement system of claim 18, in which a difference between power measured by the power measurement circuit prior to the external power input and power measured by the power measurement circuit during the external power input provides a measure of the external power input.
